(19) United States
(12) Patent Application Publication
(10) Pub. No.: US 2025/0294974 A1
(43) Pub. Date: Sep. 18, 2025

(54) DISPLAY DEVICE

(71) Applicant: Japan Display Inc., Tokyo (JP)

(72) Inventor: Hiroshi TABATAKE, Tokyo (JP)

(73) Assignee: Japan Display Inc., Tokyo (JP)

(21) Appl. No.: 19/078,405

(22) Filed: Mar. 13, 2025

(30) Foreign Application Priority Data
Mar. 14, 2024 (JP) 2024-039899

(51) Int. Cl. H10K 59/122; H10K 59/35

(52) U.S. Cl. CPC H10K 59/122; H10K 59/353

(57) ABSTRACT

According to one embodiment, a display device comprises a plurality of pixels arranged along a first direction and a second direction intersecting the first direction. Each of the plurality of pixels includes a first subpixel, a second subpixel, and a third subpixel that emit light in colors different from one another. The plurality of pixels include a first pixel and a second pixel. In the first pixel, the first subpixel and the second subpixel are arranged along the second direction and the first subpixel, the second subpixel, and the third subpixel are arranged in the first direction. The second pixel is line symmetric with the first pixel with respect to an axis parallel to the first direction. The first pixel and the second pixel are alternately arranged in the first direction.

### CROSS-REFERENCE TO RELATED APPLICATION

This application is based upon and claims the benefit of priority from Japanese Patent Application No. 2024-039899, filed Mar. 14, 2024, the entire contents of which are incorporated herein by reference.

### FIELD

Embodiments described herein relate generally to a display device.

### BACKGROUND

Recently, display devices with organic light-emitting diodes (OLED) applied thereto as display elements have been put into practical use. In this type of display devices, a technique which can improve display quality is demanded.

### BRIEF DESCRIPTION OF THE DRAWINGS

FIG. 1 is a view showing a configuration example of a display device of a present embodiment.

FIG. 2 is a schematic plan view showing an example of layouts of subpixels in pixels.

FIG. 3 is a schematic plan view showing an example of configurations of pixels.

FIG. 4 is a schematic plan view of a rib layer shown in FIG. 3.

FIG. 5 is a schematic cross-sectional view of the display device along line A-A in FIG. 3.

FIG. 6 is a schematic plan view showing an example of layouts of pixels in a display area.

FIG. 7 is a schematic plan view in which the pixels shown in FIG. 6 are enlarged.

FIG. 8 is a schematic plan view showing a display device of a comparative example.

FIG. 9 is a schematic plan view for explaining the effect of the display device of the present embodiment.

FIG. 10 is a schematic plan view showing another example of layouts of the pixels in the display area.

FIG. 11 is a schematic plan view showing still another example of layouts of the pixels in the display area.

### DETAILED DESCRIPTION

In general, according to one embodiment, a display device comprises a plurality of pixels arranged along a first direction and a second direction intersecting the first direction. Each of the plurality of pixels includes a first subpixel emitting light in a first color, a second subpixel emitting light in a second color different from the first color, and a third subpixel emitting light in a third color different from the first color and the second color. The plurality of pixels include a first pixel and a second pixel. In the first pixel, the first subpixel, the second subpixel, and the third subpixel are arranged in a first arrangement. In the second pixel, the first subpixel, the second subpixel, and the third subpixel are arranged in a second arrangement. In the first arrangement, the first subpixel and the second subpixel are arranged along the second direction and the first subpixel, the second subpixel, and the third subpixel are arranged in the first direction. The second arrangement is line symmetric with the first arrangement with respect to an axis parallel to the first direction. The first pixel and the second pixel are alternately arranged in the first direction.

Embodiments can provide a display device capable of improving display quality.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. In addition, in the specification and drawings, structural elements which function in the same or a similar manner to those described in connection with preceding drawings are denoted by like reference numbers, detailed description thereof being omitted unless necessary.

In the figures, an X axis, a Y axis, and a Z axis orthogonal to each other are described to facilitate understanding as needed. A direction along the X axis is referred to as an X direction (a first direction) and a direction along the Y axis is referred to as a Y direction (a second direction), and a direction along the Z axis is referred to as a Z direction. When various elements are viewed parallel to the Z direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

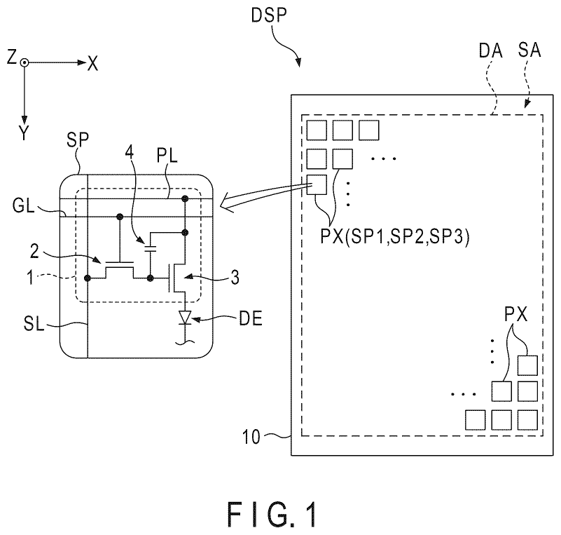

FIG. 1 is a view showing a configuration example of a display device DSP of a present embodiment. The display device DSP comprises an insulating substrate 10. The substrate 10 has a display area DA which displays an image and a surrounding area SA around the display area DA. The substrate 10 may be glass or a resinous film having flexibility.

In the present embodiment, the substrate 10 is rectangular as seen in plan view. The shape of the substrate 10 in plan view is not limited to a rectangle and may be another shape such as a square, a circle, or an oval.

The display area DA comprises a plurality of pixels PX arranged in a matrix along the X direction and the Y direction. Each pixel PX includes a plurality of subpixels SP which display different colors. The present embodiment assumes a case where each pixel PX includes a subpixel SP1 emitting light beams in red (the first color), a subpixel SP2 emitting light beams in green (the second color), and a subpixel SP3 emitting light beams in blue (the third color). However, each pixel PX may include a subpixel SP which exhibits another color such as white in addition to the subpixels SP1, SP2, and SP3 or instead of one of the subpixels SP1, SP2, and SP3.

Colors of light beams emitted by the respective subpixels SP1, SP2, and SP3 are not limited to the above example. For example, the subpixel SP1 may emit light beams in green, the subpixel SP2 may emit light beams in red, and the subpixel SP3 may emit light beams in blue. For example, the subpixel SP1 may emit light beams in red, the subpixel SP2 may emit light beams in blue, and the subpixel SP3 may emit light beams in green.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

The display area DA has a plurality of scanning lines GL supplying the pixel circuit 1 of each subpixel SP with scanning signals, a plurality of signal lines SL supplying the pixel circuit 1 of each subpixel SP with video signals, and a plurality of power lines PL. In the example of FIG. 1, the scanning lines GL and the power lines PL extend in the X direction, and the signal lines SL extend in the Y direction.

A gate electrode of the pixel switch 2 is connected to the scanning line GL. A source electrode of the pixel switch 2 is connected to the signal line SL. A drain electrode of the pixel switch 2 is connected to a gate electrode of the drive transistor 3 and the capacitor 4. A source electrode of the drive transistor 3 is connected to the power line PL and the capacitor 4. The drain electrode of the drive transistor 3 is connected to the display element DE.

The configuration of the pixel circuit 1 is not limited to the example of the figure. For example, the pixel circuit 1 may comprise more thin-film transistors and capacitors.

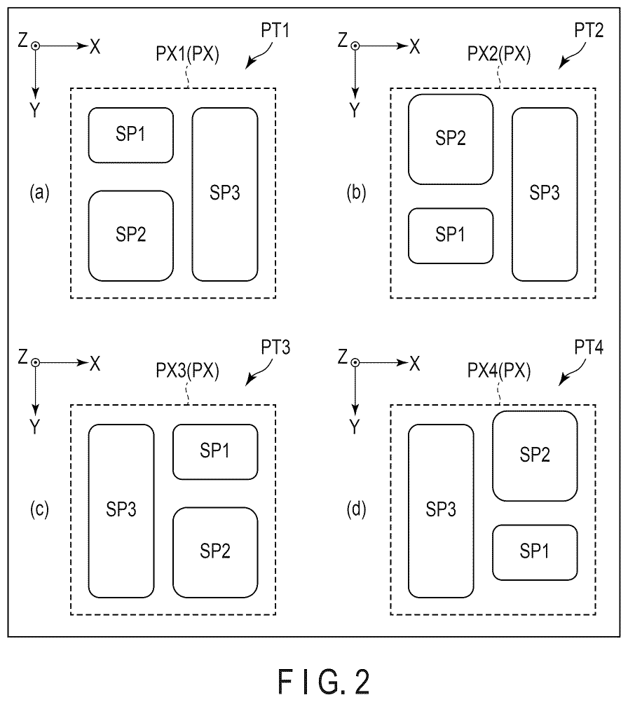

FIG. 2 is a schematic plan view showing an example of layouts of the subpixels SP1, SP2, and SP3 in pixels PX. As shown in FIG. 2 (a) to FIG. 2 (d), a plurality of pixels PX arranged in the display area DA include pixels PX1, PX2, PX3, and PX4. Respective pixels PX1, PX2, PX3, and PX4 have different arrangements of the subpixels SP1, SP2, and SP3.

FIG. 2 (a) is a schematic plan view showing an example of arrangements of the subpixels SP1, SP2, and SP3 in the pixel PX1. As shown in FIG. 2 (a), in the pixel PX1 (the first pixel), the subpixels SP1, SP2, and SP3 are arranged in an arrangement PT1 (the first arrangement). In the arrangement PT1, the subpixel SP1 and the subpixel SP2 are arranged along the Y direction, and the subpixel SP1, the subpixel SP2, and the subpixel SP3 are arranged along the X direction.

FIG. 2 (b) is a schematic plan view showing an example of arrangements of the subpixels SP1, SP2, and SP3 in the pixel PX2. As shown in FIG. 2 (b), in the pixel PX2 (the second pixel), the subpixels SP1, SP2, and SP3 are arranged in an arrangement PT2 (the second arrangement). The arrangement PT2 is line symmetric with the arrangement PT1 shown in FIG. 2 (a) with respect to an axis parallel to the X direction.

FIG. 2 (c) is a schematic plan view showing an example of arrangements of the subpixels SP1, SP2, and SP3 in the pixel PX3. As shown in FIG. 2 (c), in the pixel PX3 (the third pixel), the subpixels SP1, SP2, and SP3 are arranged in an arrangement PT3 (the third arrangement). The arrangement PT3 is line symmetric with the arrangement PT1 shown in FIG. 2 (a) with respect to an axis parallel to the Y direction.

FIG. 2 (d) is a schematic plan view showing an example of arrangements of the subpixels SP1, SP2, and SP3 in the pixel PX4. As shown in FIG. 2 (d), in the pixel PX4 (the fourth pixel), the subpixels SP1, SP2, and SP3 are arranged in an arrangement PT4 (the fourth arrangement). The arrangement PT4 is line symmetric with the arrangement PT3 shown in FIG. 2 (c) with respect to an axis parallel to the X direction.

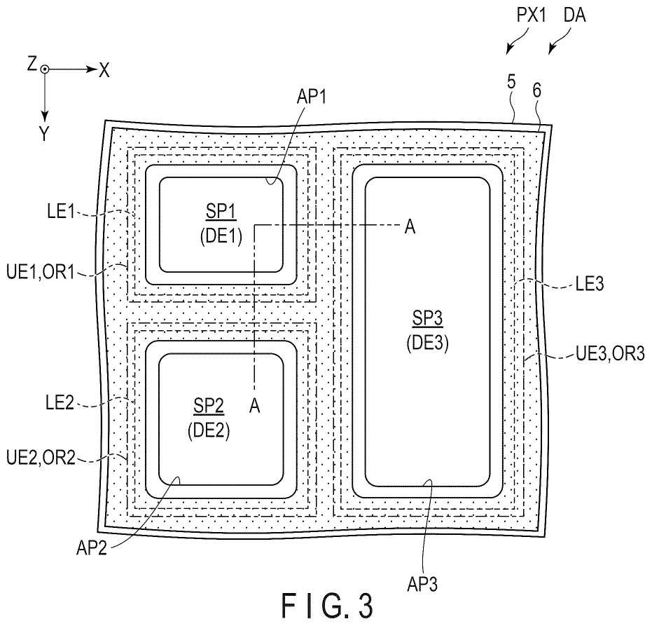

FIG. 3 is a schematic plan view showing an example of configurations of the pixel PX1. A rib layer 5 is provided in the display area DA. The rib layer 5 includes pixel apertures AP1, AP2, and AP3 (first to third pixel apertures) respectively overlapping the subpixels SP1, SP2, and SP3. In the example of FIG. 3, the pixel aperture AP1 is smaller than the pixel aperture AP2, and the pixel apertures AP1 and AP2 are smaller than the pixel aperture AP3. Thus, among the subpixels SP1, SP2, and SP3, the subpixel SP1 has the smallest aperture ratio, and the subpixel SP3 has the greatest aperture ratio. The size of each of the pixel apertures AP1, AP2, and AP3 is not limited to this example. For example, the pixel apertures AP1 and AP2 may have the same size.

The subpixel SP1 comprises a lower electrode LE1, an upper electrode UE1, and an organic layer OR1, which overlap the pixel aperture AP1. The subpixel SP2 comprises a lower electrode LE2, an upper electrode UE2, and an organic layer OR2, which overlap the pixel aperture AP2. The subpixel SP3 comprises a lower electrode LE3, an upper electrode UE3, and an organic layer OR3, which overlap the pixel aperture AP3.

Portions that overlap the pixel aperture AP1 of the lower electrode LE1, the upper electrode UE1, and the organic layer OR1 constitute a display element DE1 of the subpixel SP1. Portions that overlap the pixel aperture AP2 of the lower electrode LE2, the upper electrode UE2, and the organic layer OR2 constitute a display element DE2 of the subpixel SP2. Portions that overlap the pixel aperture AP3 of the lower electrode LE3, the upper electrode UE3, and the organic layer OR3 constitute a display element DE3 of the subpixel SP3. Each of the display elements DE1, DE2, and DE3 may further include a cap layer to be described later. The rib layer 5 surrounds each of the display elements DE1, DE2, and DE3.

A partition 6 is provided in the display area DA. The partition 6 is located above the rib layer 5 to entirely overlap the rib layer 5. In the example of FIG. 3, the partition 6 has a planar shape similar to that of the rib layer 5. In other words, the partition 6 includes an aperture in each of the subpixels SP1, SP2, and SP3. From another viewpoint, each of the rib layer 5 and the partition 6 has a grating shape as seen in plan view and surrounds each of the display elements DE1, DE2, and DE3. The partition 6 surrounds the pixel apertures AP1, AP2, and AP3 in plan view. The partition 6 functions as lines which supply the upper electrodes UE1, UE2, and UE3 with the common voltage.

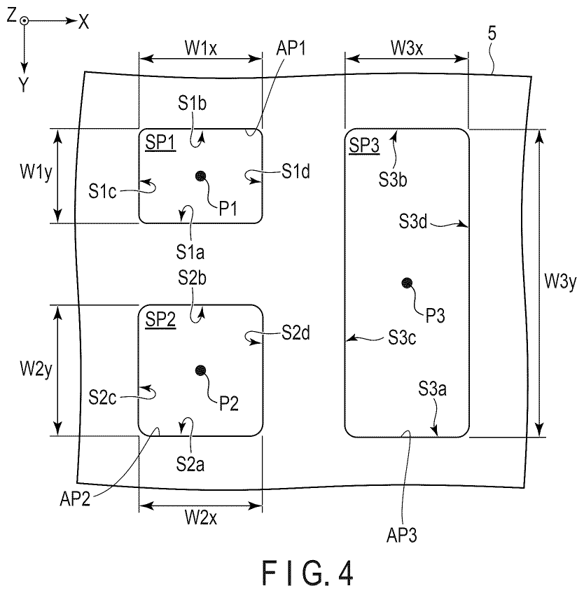

FIG. 4 is a schematic plan view of the rib layer 5 shown in FIG. 3. As shown in the figure, the four sides of the pixel aperture AP1 surrounding the subpixel SP1 are respectively defined as sides S1a, S1b, S1c, and S1d. The four sides of the pixel aperture AP2 surrounding the subpixel SP2 are respectively defined as sides S2a, S2b, S2c, and S2d. The four sides of the pixel aperture AP3 surrounding the subpixel SP3 are respectively defined as sides S3a, S3b, S3c and S3d. The sides S1a, S1b, S2a, S2b, S3a and S3b are parallel to the X direction. The sides S1c, S1d, S2c, S2d, S3c and S3d are parallel to the Y direction.

The pixel aperture AP1 has a width W1x along the X direction and a width W1y along the Y direction. The width W1x is equal to the distance between the side S1c and the side S1d along the X direction. The width W1y is equal to the distance between the side S1a and the side S1b along the Y direction. The pixel aperture AP2 has a width W2x along the X direction and a width W2y along the Y direction. The width W2x is equal to the distance between the side S2c and the side S2d along the X direction. The width W2y is equal to the distance between the side S2a and the side S2b along the Y direction. The pixel aperture AP3 has a width W3x along the X direction and a width W3y along the Y direction. The width W3x is equal to the distance between the side S3c and the side S3d along the X direction. The width W3y is equal to the distance between the side S3a and the side S3b along the Y direction.

In the example shown in FIG. 4, the width W1x is equal to the width W2x (W1x=W2x). Further, the width W1y is smaller than the width W2y (W1y<W2y). Further, the sum of the width W1y and the width W2y is smaller than the width W3y (W1y+W2y<W3y).

The pixel aperture AP1 has a center P1 (the first center). In the example shown in FIG. 4, the distance between the center P1 and the side S1c along the X direction is equal to the distance between the center P1 and the side S1d along the X direction. That is, each of the distance between the center P1 and the side S1c along the X direction and the distance between the center P1 and the side S1d along the X direction corresponds to the half of the width W1x. Similarly, the distance between the center P1 and the side S1a along the Y direction is equal to the distance between the center P1 and the side S1b along the Y direction. That is, each of the distance between the center P1 and the side S1a along the Y direction and the distance between the center P1 and the side S1b along the Y direction corresponds to the half of the width W1y.

The pixel aperture AP2 has a center P2 (the second center). In the example shown in FIG. 4, the distance between the center P2 and the side S2c along the X direction is equal to the distance between the center P2 and the side S2d along the X direction. That is, each of the distance between the center P2 and the side S2c along the X direction and the distance between the center P2 and the side S2d along the X direction corresponds to the half of the width W2x. Similarly, the distance between the center P2 and the side S2a along the Y direction is equal to the distance between the center P2 and the side S2b along the Y direction. That is, each of the distance between the center P2 and the side S2a along the Y direction and the distance between the center P2 and the side S2b along the Y direction corresponds to the half of the width W2y.

The pixel aperture AP3 has a center P3 (the third center). In the example shown in FIG. 4, the distance between the center P3 and the side S3c along the X direction is equal to the distance between the center P3 and the side S3d along the X direction. That is, each of the distance between the center P3 and the side S3c along the X direction and the distance between the center P3 and the side S3d along the X direction corresponds to the half of the width W3x. Similarly, the distance between the center P3 and the side S3a along the Y direction is equal to the distance between the center P3 and the side S3b along the Y direction. That is, each of the distance between the center P3 and the side S3a along the Y direction and the distance between the center P3 and the side S3b along the Y direction corresponds to the half of the width W3y.

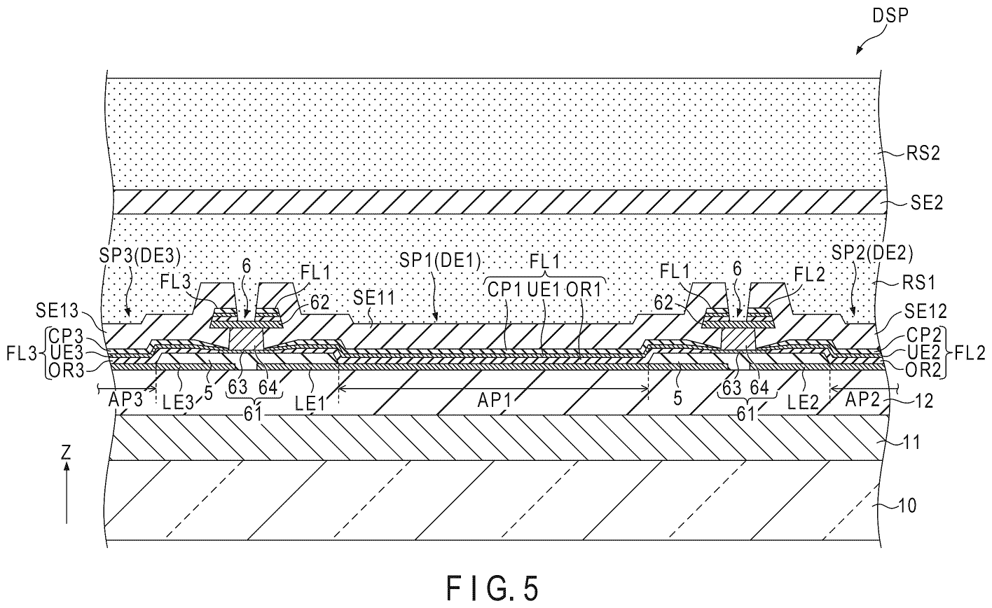

FIG. 5 is a schematic cross-sectional view showing the display device DSP along line A-A in FIG. 3. A circuit layer 11 is provided on the substrate 10 described above. The circuit layer 11 includes various circuits and lines such as the pixel circuit 1, the scanning lines GL, the signal lines SL, and the power lines PL shown in FIG. 1. The circuit layer 11 is covered with an organic insulating layer 12. The organic insulating layer 12 functions as a planarization film which planarizes irregularities formed by the circuit layer 11.

The lower electrodes LE1, LE2, and LE3 are provided on the organic insulating layer 12. The rib layer 5 is provided on the organic insulating layer 12 and the lower electrodes LE1, LE2, and LE3. End portions of the lower electrodes LE1, LE2, and LE3 are covered with the rib layer 5. Although not shown in the section in FIG. 5, the lower electrodes LE1, LE2, and LE3 are connected to the respective pixel circuits 1 (the drain electrode of the drive transistor 3 shown in FIG. 1) of the circuit layer 11 through respective contact holes provided in the organic insulating layer 12.

The partition 6 includes a conductive lower portion 61 provided on the rib layer 5 and an upper portion 62 provided on the lower portion 61. The upper portion 62 has the width greater than that of the lower portion 61. This configuration allows the respective end portions of the upper portion 62 to protrude relative to the side surfaces of the lower portion 61. This shape of the partition 6 is called an overhang shape.

In the example of FIG. 5, the lower portion 61 includes a bottom layer 63 and a stem layer 64. The bottom layer 63 is located between the stem layer 64 and the rib layer 5 and is formed to be thinner than the stem layer 64. In the example of FIG. 5, the respective end portions of the bottom layer 63 protrude relative to the side surfaces of the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. Each of the upper electrodes UE1, UE2, and UE3 contacts the side surface of the lower portion 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers which improve the extraction efficiency of light beams emitted from the organic layers OR1, OR2, and OR3, respectively.

In the following explanation, a multilayer body including the organic layer OR1, the upper electrode UE1, and the cap layer CP1 is called a stacked film FL1 (the first stacked film). A multilayer body including the organic layer OR2, the upper electrode UE2, and the cap layer CP2 is called a stacked film FL2 (the second stacked film). A multilayer body including the organic layer OR3, the upper electrode UE3, and the cap layer CP3 is called a stacked film FL3 (the third stacked film).

A part of the stacked film FL1 is located on the upper portion 62. This part is spaced apart from a part that is located around the partition 6 of the stacked film FL1 (in other words, from the part that constitutes the display element DE1). Similarly, a part of the stacked film FL2 is located on the upper portion 62. This part is spaced apart from a part that is located around the partition 6 of the stacked film FL2 (in other words, from the part that constitutes the display element DE2). Similarly, a part of the stacked film FL3 is located on the upper portion 62. This part is spaced apart from a part that is located around the partition 6 of the stacked film FL3 (in other words, from the part that constitutes the display element DE3).

Sealing layers SE11, SE12, and SE13 (first to third sealing layers), which respectively cover the stacked films FL1, FL2, and FL3 are respectively provided in the subpixels SP1, SP2, and SP3. More specifically, the sealing layer SE11 continuously covers the cap layer CP1 and the partition 6 around the subpixel SP1. The sealing layer SE12 continuously covers the cap layer CP2 and the partition 6 around the subpixel SP2. The sealing layer SE13 continuously covers the cap layer CP3 and the partition 6 around the subpixel SP3.

In the example of FIG. 5, the stacked film FL1 and the sealing layer SE11 located on the partition 6 between the subpixels SP1 and SP2 are spaced apart from the stacked film FL2 and the sealing layer SE12 located on this partition 6. The stacked film FL1 and the sealing layer SE11 located on the partition 6 between the subpixels SP1 and SP3 are spaced apart from the stacked film FL3 and the sealing layer SE13 located on this partition 6.

The sealing layers SE11, SE12, and SE13 are covered with a resin layer RS1. The resin layer RS1 is covered with the sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a protective film, and a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as polyimide. Each of the rib layer 5 and the sealing layers SE11, SE12, SE13, and SE2 is formed of an inorganic insulating material such as silicon nitride (SiNx), silicon oxide (SiOx), or silicon oxynitride (SiON). For example, the rib layer 5 is formed of silicon oxynitride, and each of the sealing layers SE11, SE12, SE13, and SE2 is formed of silicon nitride. Each of the resin layers RS1 and RS2 is formed of, for example, a resinous material (organic insulating material) such as epoxy resin or acrylic resin.

Each of the lower electrodes LE1, LE2, and LE3 has a reflective layer and a pair of conductive oxide layers covering the upper and lower surfaces of the reflective layer. The reflective layer is formed of, for example, a metallic material having excellent light-reflecting properties, such as silver. Each of the conductive oxide layers can be formed of, for example, a transparent conductive oxide such as indium tin oxide (ITO), indium zinc oxide (IZO), or indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is composed of a plurality of thin films including a light emitting layer. As an example, the organic layers OR1, OR2, and OR3 have a structure in which a hole-injection layer, a hole-transport layer, an electron blocking layer, a light emitting layer, a hole blocking layer, an electron-transport layer, and an electron-injection layer are stacked in this order in the Z direction. The organic layers OR1, OR2, and OR3 each may comprise other structures such as a tandem structure including a plurality of light emitting layers.

Each of the cap layers CP1, CP2, and CP3 comprises, for example, a multilayer structure in which a plurality of transparent layers are stacked. These transparent layers could include a layer formed of an inorganic material and a layer formed of an organic material. These transparent layers have refractive indexes different from one another. For example, the refractive indexes of these transparent layers are different from the refractive indexes of the upper electrodes UE1, UE2, and UE3 and the refractive indexes of the sealing layers SE11, SE12, and SE13. At least one of the cap layers CP1, CP2, and CP3 may be omitted.

For example, each of the bottom layer 63 and the stem layer 64 of the partition 6 is composed of a metal material. For the metal material of the bottom layer 63, for example, molybdenum, titanium, titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. The stem layer 64 may be composed of an insulating material.

For example, the upper portion 62 of the partition 6 includes a stacked layer structure comprising a lower layer composed of a metal material and an upper layer composed of a conductive oxide. For the metal material forming the lower layer, for example, titanium, titanium nitride, molybdenum, tungsten, a molybdenum-tungsten alloy, or a molybdenum-niobium alloy can be used. For a conductive oxide forming the top layer, for example, ITO or IZO can be used. The upper portion 62 may comprise a single-layer structure of a metal material. The upper portion 62 may further include a layer formed of an insulating material.

Common voltage is applied to the partition 6. This common voltage is applied to each of the upper electrodes UE1, UE2, and UE3 in contact with the side surfaces of the lower portions 61. Pixel voltages according to the video signals of the signal lines SL are applied to the lower electrodes LE1, LE2, and LE3 through the respective pixel circuits 1 provided in the subpixels SP1, SP2, and SP3.

The organic layers OR1, OR2, and OR3 emit light in response to the application of a voltage. More specifically, when a potential difference is formed between the lower electrode LE1 and the upper electrode UE1, the light emitting layer of the organic layer OR1 emits light beams of the red wavelength range. When a potential difference is formed between the lower electrode LE2 and the upper electrode UE2, the light emitting layer of the organic layer OR2 emits light beams of the green wavelength range. When a potential difference is formed between the lower electrode LE3 and the upper electrode UE3, the light emitting layer of the organic layer OR3 emits light beams of the blue wavelength range.

As another example, the light emitting layers of the organic layers OR1, OR2, and OR3 may emit light beams of the same color (for example, white). In this case, the display device DSP may comprise a color filter that converts the light beams emitted from the light emitting layers into light beams of the colors corresponding to those of the subpixels SP1, SP2, and SP3. In addition, the display device DSP may comprise a layer including quantum dots that are excited by the light beams emitted from the light emitting layers to generate the light beams of the colors corresponding to those of the subpixels SP1, SP2, and SP3.

The configuration of the pixel PX1 is shown in FIG. 3 to FIG. 5. This configuration of the pixel PX1 may apply to the pixels PX2, PX3, and PX4 shown in FIG. 2 as well.

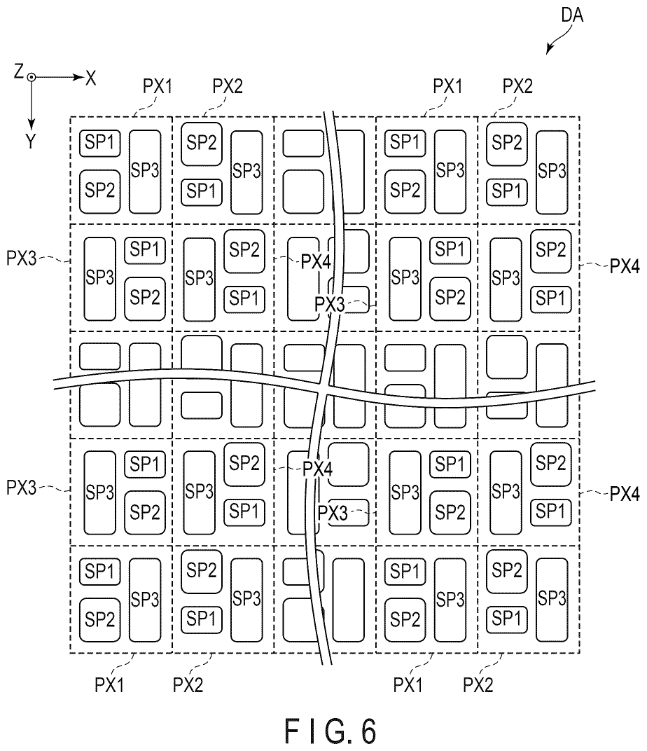

FIG. 6 is a schematic plan view showing an example of layouts of the pixels PX1 to PX4 in the display area DA. In the example shown in FIG. 6, the pixels PX1 and PX2 are alternately arranged in the X direction, and the pixels PX3 and PX4 are alternately arranged in the X direction. Further, the pixels PX1 and PX3 are alternately arranged in the Y direction, and the pixels PX2 and PX4 are alternately arranged in the Y direction. In the display area DA, rows in which the pixels PX1 and PX2 are alternately arranged in the X direction and rows in which the pixels PX3 and PX4 are alternately arranged in the X direction are alternately arranged in the Y direction. From another view point, in the display area DA, rows in which the pixels PX1 and PX3 are alternately arranged in the Y direction and rows in which the pixels PX2 and PX4 are alternately arranged in the Y direction are alternately arranged in the X direction.

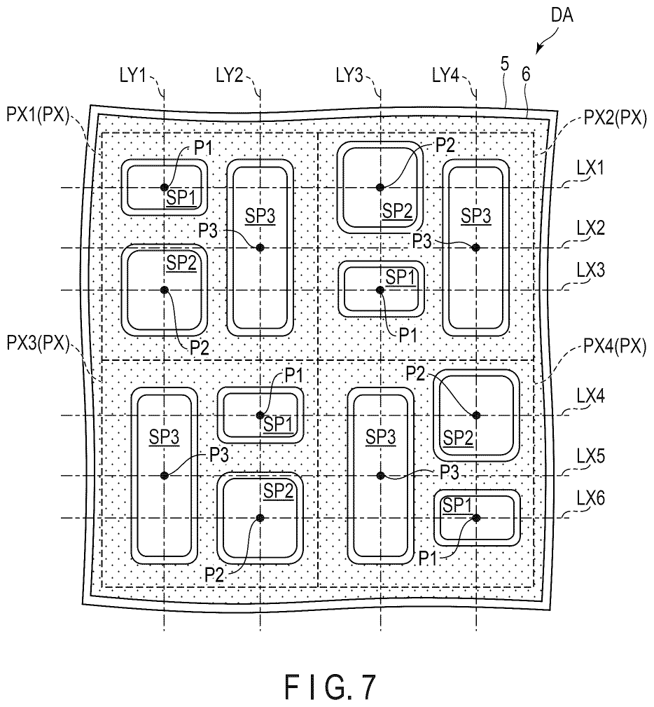

FIG. 7 is a schematic plan view in which the pixels PX1 to PX4 shown in FIG. 6 are enlarged. In an example, of two pixels PX adjacent to each other in the X direction, the center P1 of one pixel PX and the center P2 of the other pixel PX are arranged on a line parallel to the X direction. In addition, the centers P3 of two pixels PX adjacent to each other in the X direction are arranged on a line parallel to the X direction.

In the example shown in FIG. 7, the pixels PX1 and PX2 are adjacent to each other in the X direction, and the center P1 of the pixel PX1 and the center P2 of the pixel PX2 are arranged on a line LX1 parallel to the X direction. In addition, the centers P3 of the pixels PX1 and PX2 are arranged on a line LX2 parallel to the X direction. Further, the center P1 of the pixel PX2 and the center P2 of the pixel PX1 are arranged on a line LX3 parallel to the X direction.

In the example shown in FIG. 7, the pixels PX3 and PX4 are adjacent to each other in the X direction, and the center P1 of the pixel PX3 and the center P2 of the pixel PX4 are arranged on a line LX4 parallel to the X direction. In addition, the centers P3 of the pixels PX3 and PX4 are arranged on a line LX5 parallel to the X direction. Further, the center P1 of the pixel PX4 and the center P2 of the pixel PX3 are arranged on a line LX6 parallel to the X direction.

In an example, of two pixels PX adjacent to each other in the Y direction, the centers P1 and P2 of one pixel PX and the center P3 of the other pixel PX are arranged on a line parallel to the Y direction.

In the example shown in FIG. 7, the pixels PX1 and PX3 are adjacent to each other in the Y direction, and the centers P1 and P2 of the pixel PX1 and the center P3 of the pixel PX3 are arranged on a line LY1 parallel to the Y direction. Further, the centers P1 and P2 of the pixel PX3 and the center P3 of the pixel PX1 are arranged on a line LY2 parallel to the Y direction.

In the example shown in FIG. 7, the pixels PX2 and PX4 are adjacent to each other in the Y direction, and the centers P1 and P2 of the pixel PX2 and the center P3 of the pixel PX4 are arranged on a line LY3 parallel to the Y direction. Further, the centers P1 and P2 of the pixel PX4 and the center P3 of the pixel PX2 are arranged on a line LY4 parallel to the Y direction.

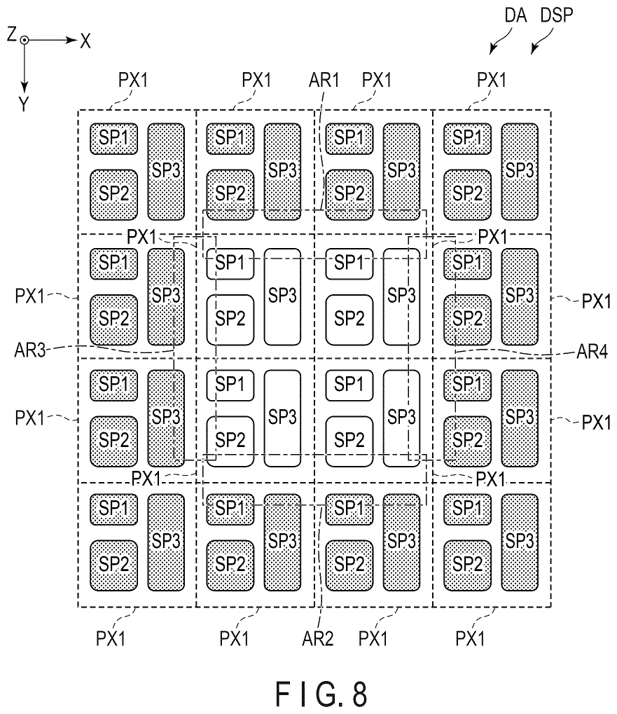

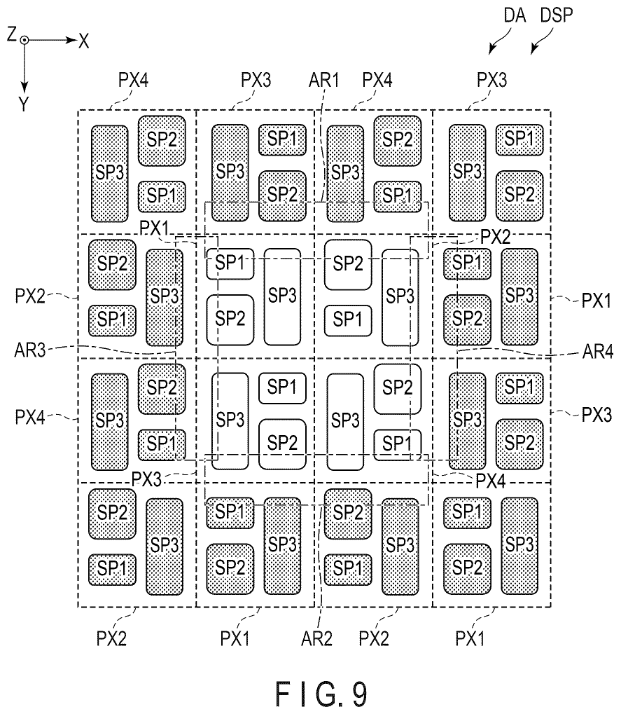

The following describes an example of effects obtained by the present embodiment with reference to FIG. 8 and FIG. 9.

FIG. 8 is a schematic plan view showing a display device DSP of a comparative example. In this comparative example, the plurality of pixels PX1 are arranged in the display area DA. In the example shown in FIG. 8, a plurality of pixels PX1 that display white (four pixels PX1 located around the center) and a plurality of pixels PX1 that surround these four pixels PX1 and display black (pixels PX1 represented by dotted patterns). An area between the subpixels SP1 and SP3 of the pixel PX1 that display white and the subpixels SP2 and SP3 of the pixel PX1 that display black is defined as a first area AR1. Similarly, an area between the subpixels SP2 and SP3 of the pixel PX1 that display white and the subpixels SP1 and SP3 of the pixel PX1 that display black is defined as a second area AR2. An area between the subpixels SP1 and SP2 of the pixel PX1 that display white and the subpixels SP3 of the pixel PX1 that display black is defined as a third area AR3. An area between the subpixels SP3 of the pixel PX1 that display white and the subpixels SP1 and SP2 of the pixel PX1 that display black is defined as a fourth area AR4.

In the configuration of the comparative example, the red subpixel SP1 and the blue subpixel SP3 overlap the first area AR1, the green subpixel SP2 and the blue subpixel SP3 overlap the second area AR2, the red subpixel SP1 and the green subpixel SP2 overlap the third area AR3, and the blue subpixel SP3 overlaps the fourth area AR4. In this configuration, a user may visually recognize magenta color, in which red and blue mix, in the first area AR1. This is disadvantageous. Similarly, in this configuration, a user may visually recognize cyan color, in which green and blue mix, in the second area AR2, and may visually recognize yellow in which red and green mix in the third area AR3, and may visually recognize blue in the fourth area AR4. These are disadvantageous. In this manner, when unintended colors are visually recognizable in a borderline between an area in which white is displayed and an area in which black is displayed, the display quality of the display device DSP may decrease.

FIG. 9 is a schematic plan view for explaining the effect of the display device DSP of the present embodiment. In the example shown in FIG. 9, pixels PX1 to PX4 that display white (the four pixels PX1 to PX4 located around the center) and pixels PX1 to PX4 that surround these four pixels PX1 to PX4 and display black (the pixels PX represented by dotted patterns). In the example shown in FIG. 9, an area between the pixels PX1 and PX2 that display white and the pixels PX3 and PX4 that display black is defined as a first area AR1. Similarly, an area between the pixels PX3 and PX4 that display white and the pixels PX1 and PX2 that display black is defined as a second area AR2. An area between the pixels PX1 and PX3 that display white and the pixels PX2 and PX4 that display black is defined as a third area AR3. An area between the pixels PX2 and PX4 that display white and the pixels PX1 and PX3 that display black is defined as a fourth area AR4.

In the present embodiment, the red subpixel SP1, the green subpixel SP2, and the blue subpixel SP3 overlap each of the first to fourth areas AR1 to AR4. In this configuration, white in which red, green, and blue mix are visually recognizable in the first to fourth areas AR1 to AR4. This clarifies the border line between white and black, increasing display quality in the display device DSP.

In the display device DSP of the present embodiment, of two pixels PX adjacent to each other in the X direction, the center P1 of one pixel PX and the center P2 of the other pixel PX are arranged on a line parallel to the X direction. Further, of two pixels PX adjacent to each other in the Y direction, the centers P1 and P2 of one pixel PX and the center P3 of the other pixel PX are arranged on a line parallel to the Y direction. This clarifies the border line between white and black, increasing display quality in the display device DSP.

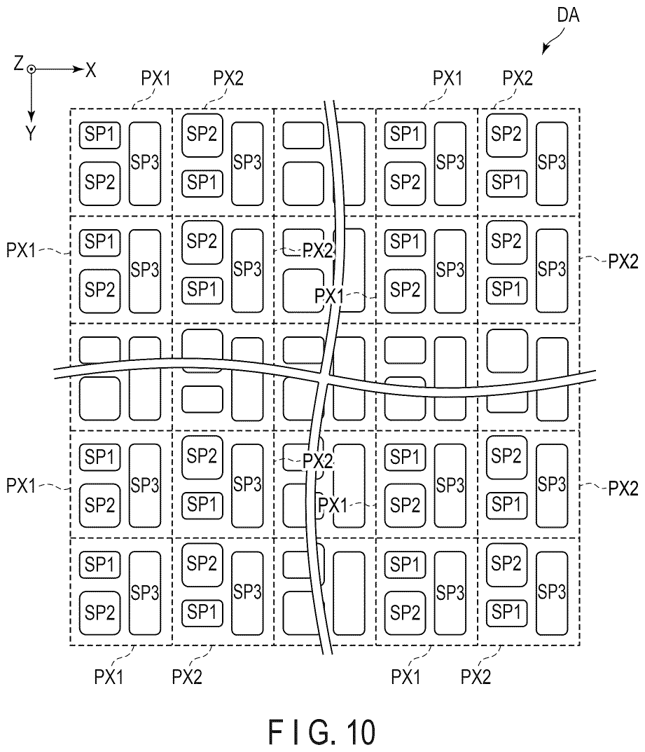

FIG. 10 is a schematic plan view showing another example of layouts of the pixels PX1 and PX2 in the display area DA. In the example shown in FIG. 10, the pixels PX1 and PX2 are alternately arranged in the X direction. In the display area DA, a row in which the pixels PX1 and PX2 are alternately arranged in the X direction is repeatedly arranged in the Y direction. From another viewpoint, the pixel PX1 is repeatedly arranged in the Y direction and the pixel PX2 is repeatedly arranged in the Y direction. Further, in the display area DA, a row in which the pixel PX1 is repeatedly arranged in the Y direction and a row in which the pixel PX2 is repeatedly arranged in the Y direction are alternately arranged in the X direction.

In the layout of the pixels shown in FIG. 10, the effects same as those described above can be achieved in the first area AR1 and second area AR2 shown in FIG. 8.

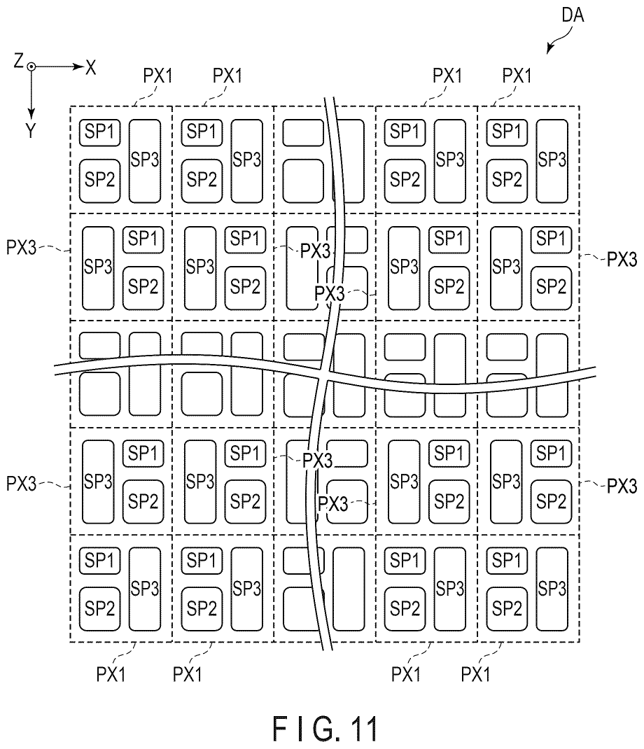

FIG. 11 is a schematic plan view showing still another example of layouts of the pixels PX1 and PX3 in the display area DA. In the example shown in FIG. 11, the pixels PX1 and PX3 are alternately arranged in the Y direction. In the display area DA, a row in which the pixels PX1 and PX3 are alternately arranged in the Y direction is repeatedly arranged in the X direction. From another viewpoint, the pixel PX1 is repeatedly arranged in the X direction, and the pixel PX3 is repeatedly arranged in the X direction. Further, in the display area DA, a row in which the pixel PX1 is repeatedly arranged in the X direction and a row in which the pixel PX3 is repeatedly arranged in the X direction are alternately arranged in the Y direction.

In the layout of the pixels shown in FIG. 11, the effects same as those described above can be achieved in the third area AR3 and fourth area AR4 shown in FIG. 8.

All of the display devices that can be implemented by a person of ordinary skill in the art through arbitrary design changes to the display device described above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device, comprising:
a plurality of pixels arranged along a first direction and a second direction intersecting the first direction, wherein
each of the plurality of pixels includes:
a first subpixel emitting light in a first color,
a second subpixel emitting light in a second color different from the first color, and
a third subpixel emitting light in a third color different from the first color and the second color,
the plurality of pixels further include:
a first pixel in which the first subpixel, the second subpixel, and the third subpixel are arranged in a first arrangement, and
a second pixel in which the first subpixel, the second subpixel, and the third subpixel are arranged in a second arrangement,
in the first arrangement, the first subpixel and the second subpixel are arranged along the second direction and the first subpixel, the second subpixel, and the third subpixel are arranged in the first direction,
the second arrangement is line symmetric with the first arrangement with respect to an axis parallel to the first direction, and
the first pixel and the second pixel are alternately arranged in the first direction.

2. The display device of claim 1, wherein
a row in which the first pixel and the second pixel are arranged in the first direction is repeatedly arranged in the second direction.

3. The display device of claim 2, wherein
the first pixel is repeatedly arranged in the second direction, and
the second pixel is repeatedly arranged in the second direction.

4. The display device of claim 1, further comprising:
a rib layer including a first pixel aperture overlapping the first subpixel, a second pixel aperture overlapping the second subpixel, and a third pixel aperture overlapping the third subpixel, wherein
the first pixel aperture has a first center,
the second pixel aperture has a second center, and
of two pixels, of the pixels, adjacent to each other in the first direction, the first center of one pixel and the second center of the other pixel are arranged on a line parallel to the first direction.

5. The display device of claim 4, wherein
the third pixel aperture has a third center, and
the third centers of two pixels, of the pixels, adjacent to each other in the first direction are arranged on a line parallel to the first direction.

6. The display device of claim 5, further comprising:
a partition including a lower portion provided above the rib layer and an upper portion having an end portion protruding relative to a side surface of the lower portion, wherein
the partition is formed into a grating shape surrounding the first pixel aperture, the second pixel aperture, and the third pixel aperture in plan view.

7. The display device of claim 1, wherein
the plurality of pixels further include:
a third pixel in which the first subpixel, the second subpixel, and the third subpixel are arranged in a third arrangement, and
a fourth pixel in which the first subpixel, the second subpixel, and the third subpixel are arranged in a fourth arrangement,
the third arrangement is line symmetric with the first arrangement with respect to an axis parallel to the second direction,
the fourth arrangement is line symmetric with the third arrangement with respect to an axis parallel to the first direction, and
the third pixel and the fourth pixel are alternately arranged in the first direction.

8. The display device of claim 7, wherein
a row in which the first pixel and the second pixel are alternatively arranged in the first direction and a row in which the third pixel and the fourth pixel are alternatively arranged in the first direction are alternately arranged in the second direction.

9. The display device of claim 8, wherein
the first pixel and the third pixel are alternately arranged in the second direction, and
the second pixel and the fourth pixel are alternately arranged in the second direction.

10. The display device of claim 7, further comprising:
a rib layer including a first pixel aperture overlapping the first subpixel, a second pixel aperture overlapping the second subpixel, and a third pixel aperture overlapping the third subpixel, wherein
the first pixel aperture has a first center,
the second pixel aperture has a second center, and
of two pixels, of the pixels, adjacent to each other in the first direction, the first center of one pixel and the second center of the other pixel are arranged on a line parallel to the first direction.

11. The display device of claim 10, wherein
the third pixel aperture has a third center, and
the third centers of two pixels, of the pixels, adjacent to each other in the first direction are arranged on a line parallel to the first direction.

12. The display device of claim 11, wherein
of two pixels, of the pixels, adjacent to each other in the second direction, the first center and the second center of one pixel and the third center of the other pixel are arranged on a line parallel to the second direction.

13. The display device of claim 4, wherein
a width along the second direction of the first pixel aperture is smaller than a width along the second direction of the second pixel aperture.

14. The display device of claim 4, wherein
a width along the first direction of the first pixel aperture is equal to a width along the first direction of the second pixel aperture.

15. The display device of claim 4, wherein
a sum of a width along the second direction of the first pixel aperture and a width along the second direction of the second pixel aperture is smaller than a width along the second direction of the third pixel aperture.

16. The display device of claim 4, wherein
the first pixel aperture is smaller than the second pixel aperture.

17. The display device of claim 16, wherein
each of the first pixel aperture and the second pixel aperture is smaller than the third pixel aperture.

18. The display device of claim 1, wherein
the first color is red,
the second color is green, and
the third color is blue.

19. The display device of claim 1, wherein
the first color is green,
the second color is red, and
the third color is blue.

20. The display device of claim 1, wherein
the first color is red,
the second color is blue, and
the third color is green.
